(19) United States
(12) Patent Application Publication
(10) Pub. No.: US 2025/0033954 A1
(43) Pub. Date: Jan. 30, 2025

(54) 3D Heterogeneously Integrated Power Electronic Building Blocks

(71) Applicant: Teledyne Scientific & Imaging, LLC, Thousand Oaks, CA (US)

(72) Inventors: Vivek Mehrotra, Simi Valley, CA (US); Keisuke Shinohara, Thousand Oaks, CA (US); Robert Mihailovich, Newbury Park, CA (US); Philip Stupar, Oxnard, CA (US); Alexandros P. Papavasiliou, Thousand Oaks, CA (US)

(21) Appl. No.: 18/784,021

(22) Filed: Jul. 25, 2024

Related U.S. Application Data
(60) Provisional application No. 63/515,697, filed on Jul. 26, 2023.

(51) Int. Cl. B81B 7/00; B81C 1/00

(52) U.S. Cl. CPC B81B 7/007; B81C 1/00341; B81B 2207/096

(57) ABSTRACT

A power converter comprising a substrate, a control circuit disposed on the substrate; and a first circuit stack disposed on the substrate and coupled to the control circuit. The first circuit stack is in a stacked configuration. The first circuit stack comprises a first switch layer, a first interposer layer electrically coupled to the first switch layer, a second interposer layer electrically coupled to the first interposer layer, a first gate drive layer disposed between and electrically coupled to the first interposer layer and the second interposer layer, and a first inductor layer electrically coupled to the first gate drive layer.

### PRIORITY

The present application claims priority under 35 U.S.C. Section 119 (e) from Provisional Application 63/515,697, entitled “3D Heterogeneously Integrated Power Electronic Building Blocks,” filed on Jul. 26, 2023, the entire contents of each are incorporated herein by reference.

### GOVERNMENT CONTRACT

This invention was made with government support under Contract No. 140D0423C0038 awarded by the Department of Interior. The government has certain rights in the invention.

### FIELD

This disclosure relates generally to the field of power converters.

### SUMMARY

In part, in one aspect, the disclosure relates to a power converter comprising a substrate, a control circuit disposed on the substrate, and a first circuit stack disposed on the substrate and coupled to the control circuit. The first circuit stack is in a stacked configuration. The first circuit stack comprises a first switch layer, a first interposer layer electrically coupled to the first switch layer, a second interposer layer electrically coupled to the first interposer layer, a first gate drive layer disposed between and electrically coupled to the first interposer layer and the second interposer layer, and a first inductor layer electrically coupled to the first gate drive layer.

Although, the disclosure relates to different aspects and embodiments, it is understood that the different aspects and embodiments disclosed herein can be integrated, combined, or used together as a combination system, or in part, as separate components, devices, and systems, as appropriate. Thus, each embodiment disclosed herein can be incorporated in each of the aspects to varying degrees as appropriate for a given implementation. Further, the Gallium Nitride power devices used as a switch, Silicon-MEMS capacitors, Silicon-MEMS inductor components and the method of creating a vertically stacked chip capable of processing power and converting from one voltage level to another disclosed herein can be used without limitation.

These and other features of the applicant's teachings are set forth herein.

### BRIEF DESCRIPTION OF THE FIGURES

Unless specified otherwise, the accompanying drawings illustrate aspects of the innovations described herein. Referring to the drawings, wherein like numerals refer to like parts throughout the several views and this specification, several embodiments of presently disclosed principles are illustrated by way of example, and not by way of limitation. The drawings are not intended to be at scale. A more complete understanding of the disclosure may be realized by reference to the accompanying drawings in which:

FIG. 1 is an existing power converter.

FIG. 2 illustrates a method of daisy chaining power converters.

FIG. 3 is a state-of-the-art buck converter.

FIG. 4A is a graph of the voltage and current during switching for the buck converter of FIG. 3.

FIG. 4B is a graph of the power loss during switching for the buck converter of FIG. 3.

FIG. 5 is a state-of-the-art power converter with horizontal power flow to the load it is driving.

FIG. 6 is an integrated 3D HI-PEBB voltage regulator, according to an aspect of this disclosure.

FIG. 7 is a plan view of a vertically stacked voltage regulator composed of four building blocks, where each building block is composed of vertically stacked chips, according to an aspect of this disclosure.

FIG. 8 illustrates the two building blocks for a vertically stacked voltage regulator composed of two building blocks, where each building block is composed of vertically stacked chips, according to an aspect of this disclosure.

FIG. 9 illustrates a cross-sectional view of a vertically stacked voltage regulator illustrating the two main building blocks or power converter chips, according to aspects of this disclosure.

FIG. 10 is a detailed view of FIG. 9 illustrating the interconnects, vias and pads, according to aspects of this disclosure.

FIG. 11 is an exploded three-dimensional view of a voltage regulator composed of the two building blocks, in accordance with FIG. 9 and FIG. 8.

FIG. 12A is an illustration of a switch, according to an aspect of the present disclosure.

FIG. 12B is an illustration of a switch, according to an aspect of the present disclosure.

FIG. 13 is a circuit stack composed of three building blocks, according to an aspect of this disclosure.

FIG. 14 is a circuit stack of FIG. 7 composed of four building blocks, according to an aspect of this disclosure.

FIG. 15 is a cross-sectional view of a Silicon-MEMS inductor, according to aspects of this disclosure.

FIG. 16 illustrates the plan view of a 3D Silicon-MEMS inductor, according to an aspect of the present disclosure.

FIG. 17 illustrates a 3D Silicon-MEMS Trench Capacitors, according to an aspect of the present disclosure.

FIG. 18 illustrates a 3D Silicon-MEMS Trench Capacitors, according to an aspect of the present disclosure.

FIG. 19 illustrates the load efficiency and power density of common power converters in comparison with the power converter of the present disclosure, according to aspects of this disclosure.

FIG. 20 illustrates a graph of the on time of high-side switch (for example, S₁ in FIG. 3) with switching frequency in a common buck converter compared to the on time of a high-side switch (for example, high side switches in FIG. 14) with switching frequency in a power converter (referred to as 4-cell SC-Buck) of the present disclosure.

FIG. 21A illustrates the voltage and current of the high-side switches during switching in a power converter of the present disclosure.

FIG. 21B illustrates the turn on and turn off losses during switching in the power converter of the present disclosure.

FIG. 22A illustrates assembling a generally known power converter.

FIG. 22B illustrates the comparison in assembling the power converter of the present disclosure, according to an aspect of the present disclosure.

### DETAILED DESCRIPTION

This disclosure relates to power converters. Existing power converters are built in 2D with limited integration, creating a trade-off between switching frequency, efficiency, power density, and transient response. Additionally, existing on-chip integration is restricted to Silicon with no integration of efficient wide band gap devices and passive components (inductors and capacitors). Existing power converters lack modularity and voltage or current scaling, which prevents usage of common building blocks (e.g. circuits or chips) that can be arranged to meet different input and output voltages and/or output currents.

This disclosure generally is directed to a three-dimensional stack of chips in circuits that enable high power density (>1000 W/in³) at high efficiency (>90%) and allow proximity to the load for superior transient response (>100 A/microsecond). The disclosed stack of chips in circuits also enables voltage scaling by using an appropriate combination of cell-based stack of building blocks arranged according to a scalable circuit topology. Voltage scaling allows a wide range of inputs, e.g., 48V/28V/12V, and outputs, e.g., 0.5V to 5V. Current scaling is enabled by tiling different cells composed of a stack of chips in circuits. The power path impedance between output terminals and load is reduced, which enables superior transient response (>100 A/microsecond) and reduced radiated and electrical noise.

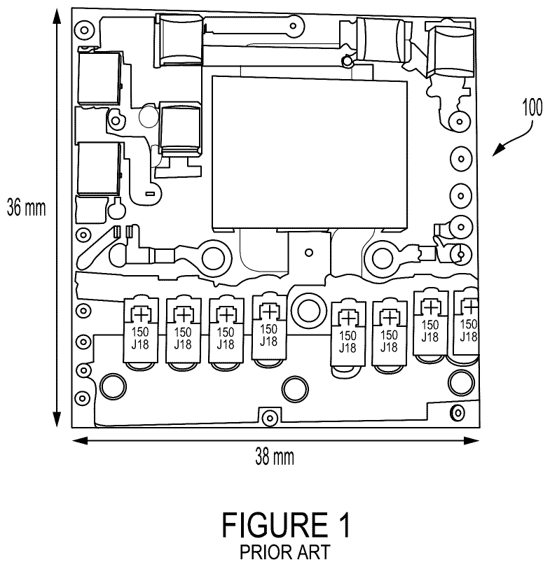

With reference now to the figures, FIG. 1 is an existing power converter 100. Existing power converters 100 are built in 2D with limited integration, creating a trade-off between switching frequency, efficiency, power density, and transient response. In existing power converters 100, on-chip integration is restricted to silicon only with no integration of wide band gap (WBG) devices, such as gallium nitride (GaN), and passives. In addition, there is no modularity nor voltage/current scaling with the existing power converter 100.

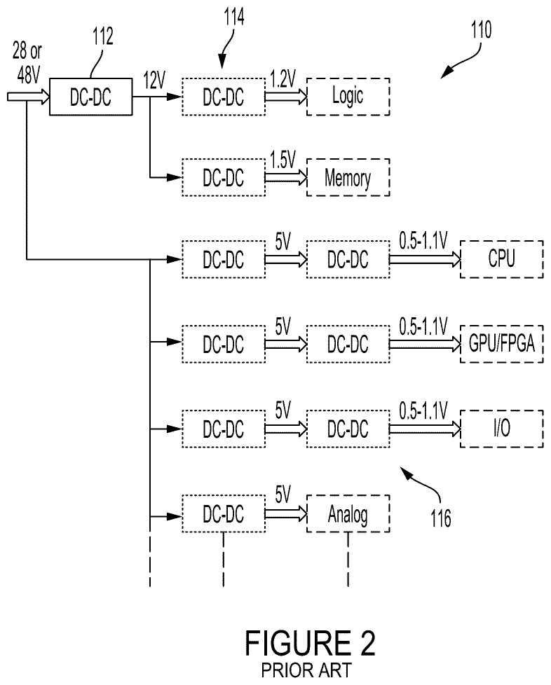

FIG. 2 illustrates a daisy chain 110 of power converters. The daisy chain 110 of converters creates lower system efficiency as the total overall efficiency decreases with each converter in the chain. The daisy chain 110 comprises a first converter 112, a second converter 114, and a third converter 116 for up to three (or more) levels of power conversion, as shown in the daisy chain 110.

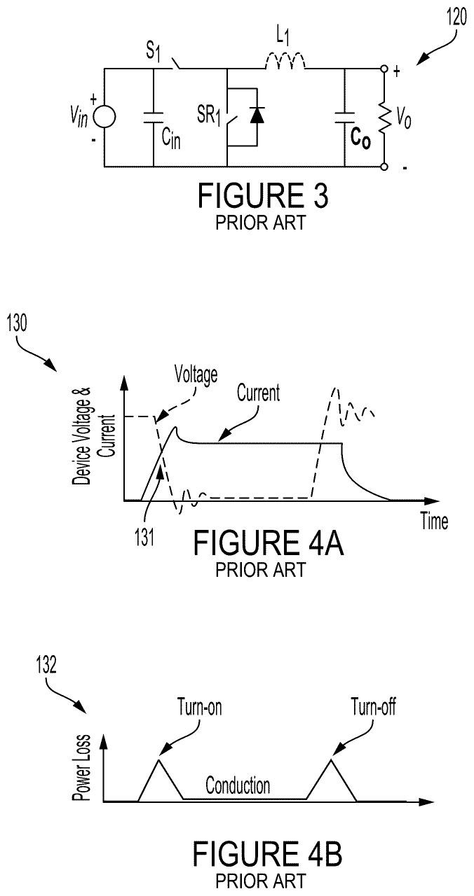

In a daisy chain, it is not possible to directly convert from a higher input voltage to a lower voltage because it would require an extremely short on-time of the high-side switch (S1) in the state-of-the-art buck converter (shown in FIG. 3). As shown, converting 28 or 48 volts to 0.5-1.1 volts requires 3 levels of conversion. The switch on time in state-of-the-art buck converter is equal to the output voltage divided by the input voltage times the switching frequency (tₒₙ=vₒᵤₜ/f_{sw}*vᵢₙ). A small on-time cannot be accurately controlled, which restricts switching frequency (f_{sw}) to a low value. However, higher switching frequency is required to reduce the size of passives and increase transient response for higher control bandwidth. Moreover, a circuit with 2D integration and size further prohibits proximity to load to meet transient response and reduce the impact of parasitics and interconnect losses. These factors have a negative impact on dynamic voltage scaling to follow fast changes in load activity and on envelope tracking of power amplifiers, both of which increase system efficiency.

FIG. 3 is a state-of-the-art buck converter 120. A buck converter 120 is a DC-to-DC converter which steps down voltage (while stepping up current) from its input (supply) to its output (load). It is a class of switched-mode power supply. The buck converter converts the high voltage into a low voltage with higher current.

FIG. 4A is a graph 130 of the voltage and current for the buck converter 120 of FIG. 3. The switch S₁ 122 in the buck converter 120 experiences a high input voltage and current during switching, resulting in high switching loss.

FIG. 4B is a graph 132 of the power loss for the buck converter 120 of FIG. 3, illustrating switching losses of the switch S₁ during turn-on and turn-off events and conduction loss during on-period. The cross-over 131 between input voltage and current during turn on and turn off events are directly related to power loss.

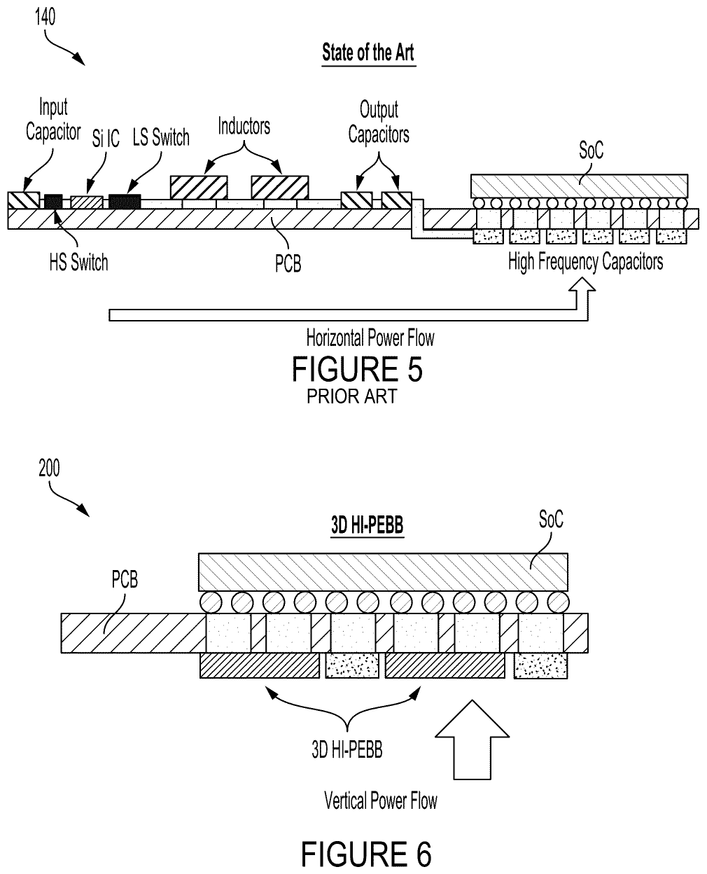

FIG. 5 is a power converter 140. The power converter 140 is utilized for computing chips to create lower drive voltages generally from 0.5 V to 1.8 V at higher currents. The input voltage is generally higher than the drive voltage. Direct conversion from higher input voltage (28V or 48V) for lower distribution loss requires multi-stage conversion (e.g., 48V to 5V, then to 1V or lower). The system on chip components draw different currents and voltages at different positions or nodes. This creates the need for scalability with common building blocks, which is not feasible with state-of-the-art power converters. Moreover, the horizontal power flow with state-of-the-art power converters creates inductive noise and limits transient response. As a result, many high frequency capacitors are required in proximity to the load.

Inductive noise on power connections affects power quality, requiring additional capacitors. This creates a need for modular and integrated voltage regulators with low resistive losses and parasitic inductances. The state-of-the-art DC-DC power converter is located far from the load. This creates a long and lossy path for horizontal current flow. This limits voltage regulation and transient response (measured in A/μs).

FIG. 6 is an integrated 3D HI-PEBB voltage regulator 200, according to an aspect of this disclosure. The integrated 3D HI-PEBB voltage regulator (e.g., power converter) 200 has a higher efficiency and reduced passive component sizes due to 3D integration, lower losses, higher effective frequency at load terminals, and direct conversion from higher input voltage (for example, direct conversion from 28V or 48V input to lower voltages such as <1V). In one aspect, the vertical current flow creates precise voltage regulation and a higher transient response measured in amps per microsecond. In one aspect, the voltage and current scaling provides direct conversion.

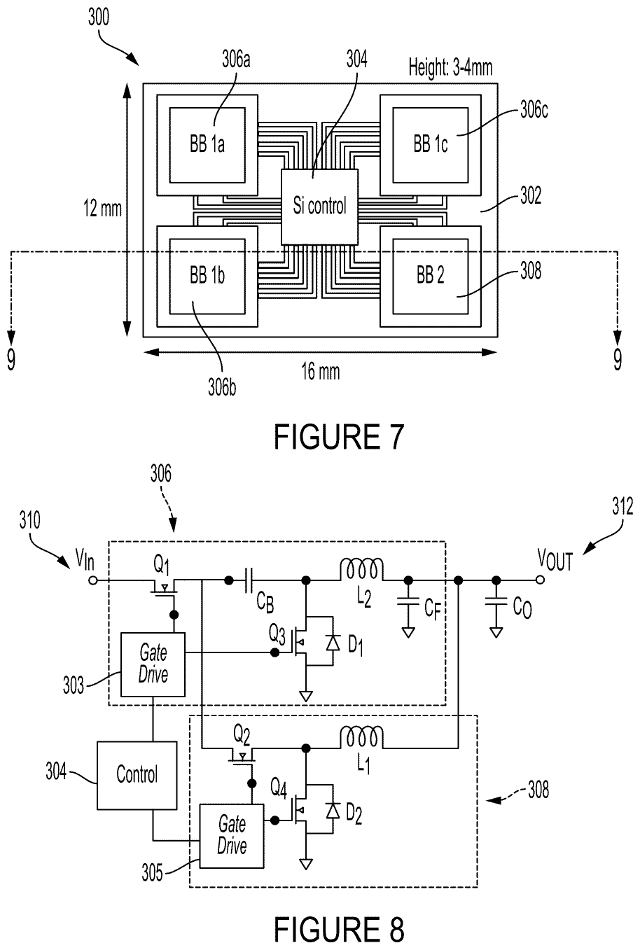

FIG. 7 is a vertically stacked power converter 300, according to an aspect of this disclosure. The power converter 300 comprises a substrate 302 with a control circuit 304 disposed on the substrate 302. The power converter 300 also comprises a first circuit stack 308 (e.g. building block BB 2) and a plurality of second circuit stacks 306a, 306b, 306c (e.g. building blocks BB 1a, 1b and 1c). The control circuit 304 is coupled to the first circuit stack 308 and the plurality of second circuit stacks 306a, 306b, 306c. A vertically stacked power converter enables low impedance to the load, expanded duty cycle, higher efficiency, and voltage and current scaling. FIG. 7 is arranged in accordance with the circuit in FIG. 14. The size of the vertically stacked voltage regulator is 12 mm by 16 mm whereas the voltage regulator shown in FIG. 1 is 36 mm by 38 mm.

FIG. 8 illustrates two circuit stacks of the vertically stacked voltage regulator, according to an aspect of this disclosure.

The first circuit stack 308 comprises an inductor L₁ and a plurality of switches Q₂, Q₃ coupled to the gate drive 305. The gate drive is controlled by a control circuit 304. A diode D₂ may be coupled in parallel with the switch Q₄.

The second circuit stack 306 comprises a capacitor C_{B}, an inductor L₂, and a plurality of switches Q₁, Q₃. The switches Q₁, Q₃ are controlled via a gate drive 303 controlled by the control circuit 304. The control circuit 304 is to control both the first 308 and second circuit stack 306. The second circuit stack 306 receives an input voltage 310. The input voltage (Vin) is regulated to an output voltage (Vout) by the first circuit stack 308 and the second circuit stack 306. The control circuit 304 controls the output voltage and switching time of the switches Q₁, Q₂, Q₃, Q₄. A diode D₁ may be coupled in parallel with the switch Q₃.

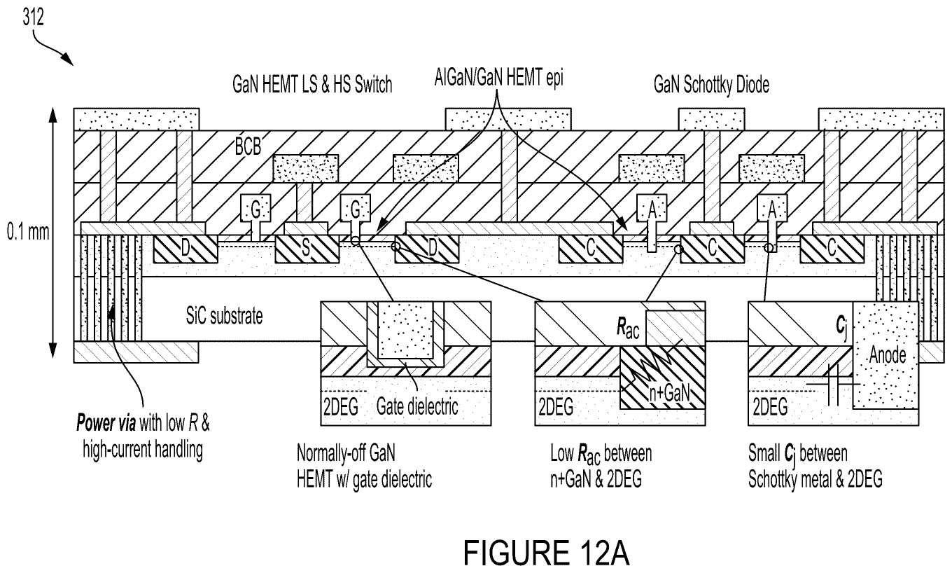

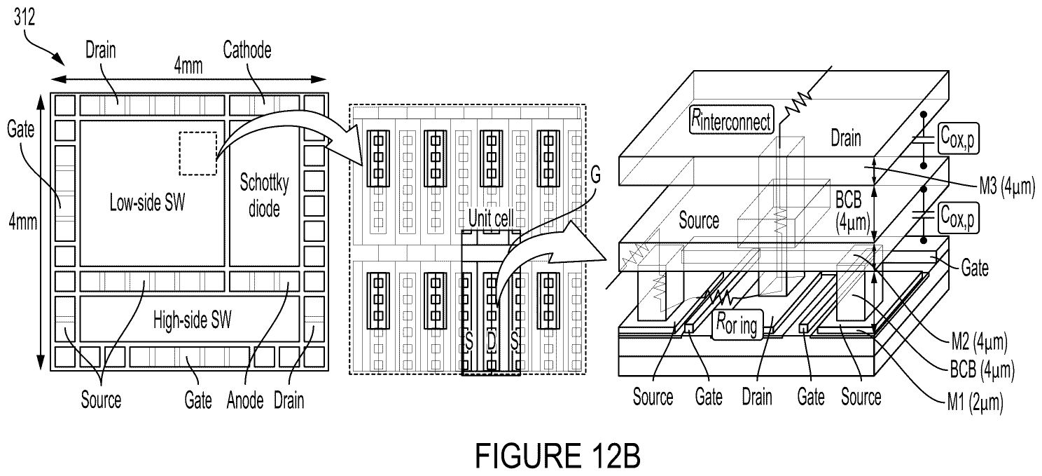

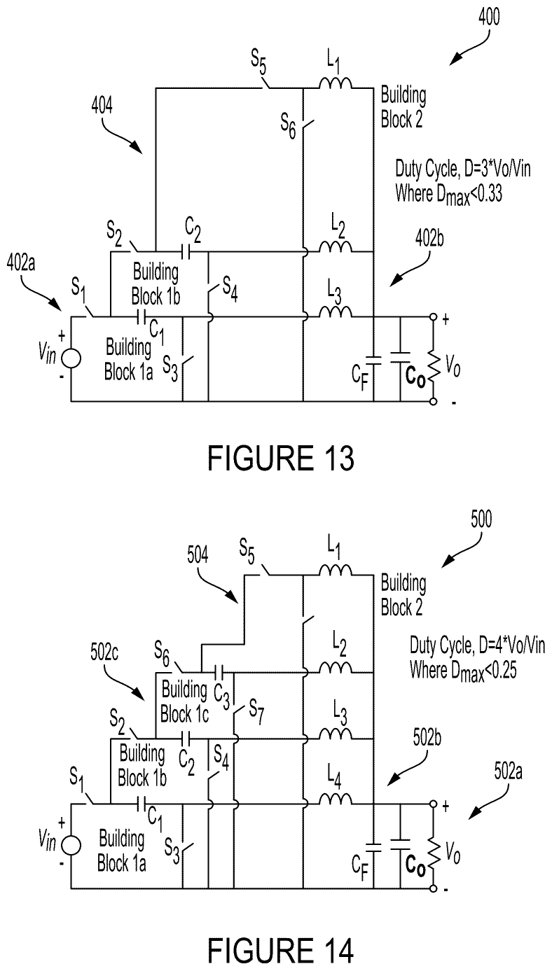

In one aspect, the switches Q₁, Q₂, Q₃, Q₄ are integrated GaN switches, where all required switches and diodes within a cell are integrated on the same chip (as shown in FIGS. 12A-12B). The GaN switches have 20-100 times higher Rₒₙ*Q_{g} compared to silicon, which lowers switching, conduction and gate drive losses. In general, a silicon pulse width modulator and gate driver, and Si-MEMS inductor and capacitor chips, and high and low side GaN switches with diodes are assembled in a vertical fashion and interconnected in accordance with the circuit of FIG. 8 (2-cell), FIG. 13 (3-cell), or FIG. 14 (4-cell).

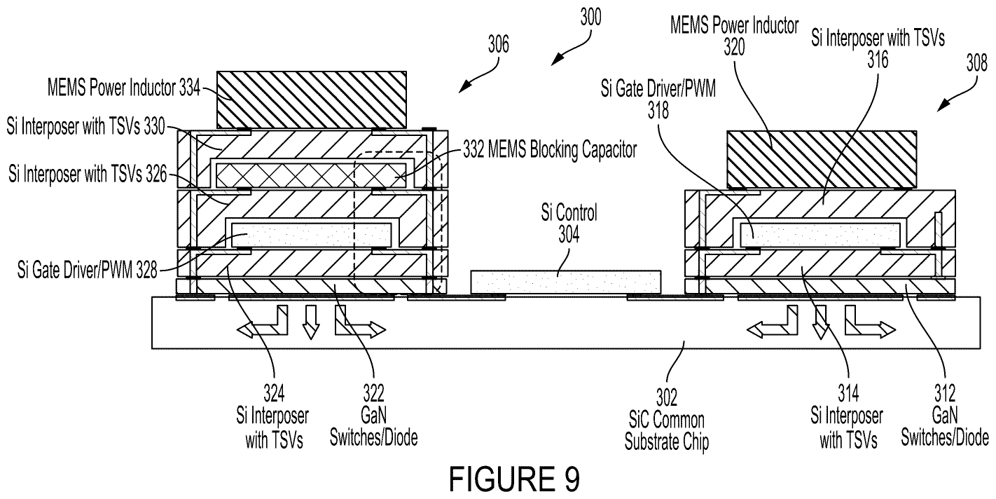

FIG. 9 illustrates a cross-sectional view of a power converter 300, according to aspects of this disclosure. The power converter 300 comprises a substrate 302 and a control circuit 304 disposed on the substrate 302. The first circuit stack 308 is disposed on the substrate 302 and electrically coupled to the control circuit 304. The first circuit stack 308 is in a stacked configuration. The first circuit stack 308 comprises a first switch layer 312 and a first interposer layer 314 electrically coupled to the first switch layer 312. The first circuit stack 308 also comprises a second interposer layer 316 electrically coupled to the first interposer layer 314. A first gate drive layer 318 is disposed between and electrically coupled to the first interposer layer 314 and the second interposer layer 316. A first inductor layer 320 is electrically coupled to the underlying chip layers—the second interposer layer 316, the first interposer layer 314, the first switch layer 312, and the first gate drive layer 318.

In one aspect, the power converter 300 comprises a second circuit stack 306 disposed on the substrate 302 and electrically coupled to the control circuit 304. The second circuit stack 306 is in a stacked configuration. The second circuit stack 306 comprises a second switch layer 322 disposed on the substrate 302. A third interposer layer 324 is electrically coupled to the second switch layer 322. A fourth interposer layer 326 is electrically coupled to the third interposer layer 324. A second gate drive layer 328 is disposed between and electrically coupled to the third interposer layer 324 and the fourth interposer layer 326. A capacitor layer 332 disposed within a fifth interposer layer 330 and electrically coupled to the fourth interposer layer 326. A second inductor layer 334 is electrically coupled to the underlying chip layers—the fifth interposer layer 330, fourth interposer layer 326, the third interposer layer 324, the second switch layer 322, and the capacitor layer 332.

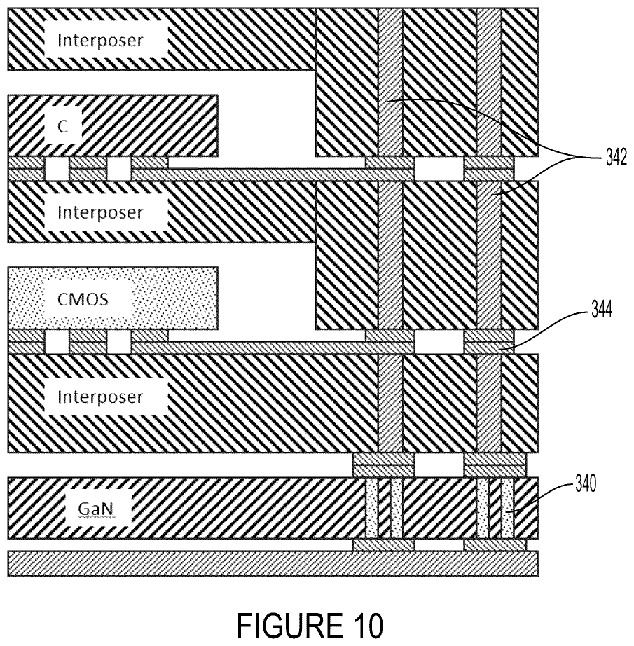

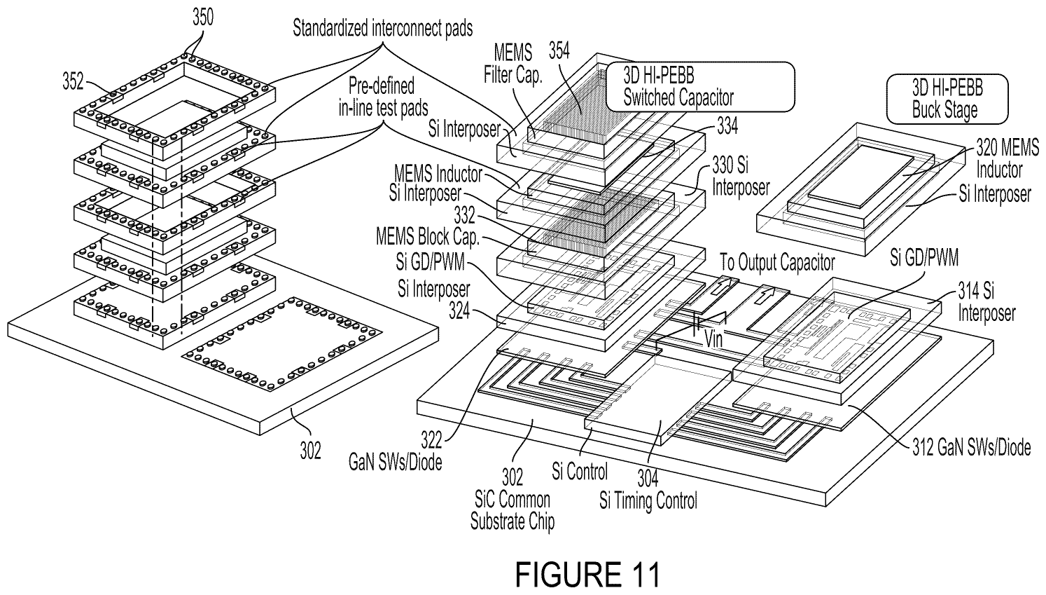

The interposer layers 314, 316, 324, 326, 330 define a plurality of through silicon vias for electrical coupling (shown in FIGS. 10 and 11). In one aspect, the layers of the circuit stacks 306, 308 are connected by interconnects between the layers. In one aspect, the interconnects are comprised of copper. In one aspect, the interconnects extend through the interposer layer and are disposed on a surface of the interposer layer.

In one aspect, a circuit stack 306, 308 comprises a plurality of capacitor layers 332 between the second gate drive layer 328 and the second inductor 334.

In one aspect, the control circuit 304 is to control the timing of the first and second switch layer 312, 322. In one aspect, the control circuit 304 controls which of the first and second circuit stack 308, 306 receives an input voltage and modulates the output voltage. The control of the timing of the switches controls the output voltage.

In one aspect, the capacitor layer 332 comprises a microelectromechanical system (MEMS) blocking capacitor.

In one aspect, the inductor 320, 334 comprises a microelectromechanical system (MEMS) power inductor.

In one aspect, the switch layers 312, 322 are comprised of gallium nitride power devices illustrated further in FIGS. 12A-12B.

In one aspect, the power converter 300 further comprises a plurality of second circuit stacks disposed on the substrate 302 and electrically coupled to the control circuit 304.

Vertically stacked circuits (e.g., second circuit stack 306 and first circuit stack 308) enable efficient and regulated power delivery at the point-of-load. The decreased power path impedance allows the circuit to meet load transients and reduced radiated and electrical noise. The vertical circuit stacks enable current scaling: tiles of n-cell 3D HI-PEBBs share load current. The number of cells used in the vertical circuit stack enables voltage scaling, in accordance with FIG. 8, 13 or 14. In addition, the vertical circuit stacks reduce parasitic and interconnect losses.

FIG. 10 is a detailed view of FIG. 9. Each interposer layer defines a plurality of through silicon vias. In one aspect, interconnects 342 are disposed in the through silicon via and form a fanout disposed on the interposer layer. In one aspect, the interconnects 342 comprise copper and are disposed between the interposer layers. Between the interconnects 342 is a bonding layer 344, which can be Au—AuSn eutectic bonding or Au—Au thermocompression bonding, or Cu—Cu thermocompression bonding or Cu—Sn bonding. In one aspect, the thickness of the bonding layer 344 is approximately 20 micrometers.

The electrical interconnects 342 have high current handling (˜10 A) with low interconnect resistance (<1 mΩ). The GaN switch circuit layer defines a via with a second interconnect 340. In one aspect, the second interconnect 340 comprises gold. The high thermal conductivity of the substrate with GaN chip at the bottom aids in heat removal. In one aspect, the substrate 302 comprises silicon carbon (SiC).

FIG. 11 is an exploded 3-dimensional view of a power converter chip, according to an aspect of the present disclosure. The control circuit 304 is disposed on the substrate 302. The switch layers 312, 322 are electrically coupled to the control circuit 304. Each switch layer 312, 322 is coupled to a corresponding interposer layer 314, 324. Each circuit stack also comprises an inductor layer 320, 334 coupled to an interposer layer 314, 324, 330. In one aspect, a circuit stack comprises a capacitor layer 332 within an interposer layer 330. The interposer layers 314, 324, 330 define through silicon vias 350. In one aspect, the circuit stack comprises a filtering capacitor layer 354. In one aspect, the interposer layers 314, 324, 330 define corresponding through silicon vias 350, such that each interposer layer 314, 324, 330 defines vias at the same location to line up when in a stacked configuration.

Standardized chip assembly process is enabled by silicon interposer chips with through silicon vias 350 and interconnect lines/pads, accommodating any chips with arbitrary dimensions and pad locations. In one aspect, there are in-line test pads 352 built in the interposer chips. In one aspect, the interposer layers comprise silicon. Materials for bonding include Au—Au/Sn, Au—Au, Cu—Cu, and Cu—Cu/Sn. The possible range of chip sizes vary from 3 mm by 3 mm chips to 10 mm by 10 mm.

FIGS. 12A and 12B are an illustration of an integrated gallium nitride switch, according to an aspect of the present disclosure. In one aspect, the integrated gallium nitride switch is the switch layer in FIGS. 7-11. In one aspect, the switch layers are comprised of gallium nitride with integrated high side and low side switches and diodes. Table 1 illustrates the differences between GaN and Si used as a switch and diode.

TABLE 1

| | | |
|---|---|---|
| Parameter | Value | Unit |

GaN HEMT Switch

| | | | | |
|---|---|---|---|---|
| BV | 24 | 60 | 100 | V |
| Vth | 0.5 | 0.5 | 0.5 | V |
| Lg | 0.15 | 0.15 | 0.15 | μm |
| Ron | 2.91 | 3.14 | 3.39 | Ω*mm |
| Qg | 8.3 | 11.2 | 14.4 | Pc/mm |
| Imax | 0.8 | 0.8 | 0.8 | A/mm |
| Ron*Qg | 24.2 | 35.2 | 48.8 | mΩ*nC |
| Ron*Qg | 50 | 200 | 600 | mQ*nC |

GaN Nano Schottky Diode

| | | | | |
|---|---|---|---|---|
| BV | 24 | 60 | 100 | V |
| Vf | 0.6 | 0.6 | 0.6 | V |
| Lac | 0.24 | 0.60 | 1.00 | μm |
| Rs | 0.18 | 0.23 | 0.29 | Q*mm |
| Cjo | 760 | 760 | 760 | fF/mm |
| Imax | 1.0 | 1.0 | 1.0 | A/mm |
| Rs*Cj | 137 | 178 | 223 | fsec |

SOA GaN Schottky diode

| | | | | |
|---|---|---|---|---|
| Rs*Cj | 240 | 1600 | 2950 | fsec |

FIG. 13 is a circuit stack 400, according to an aspect of the present disclosure. The circuit stack 400 comprises three cells or layers, a first capacitor layer 402a, a second capacitor layer 402b, and an inductor layer 404. The maximum duty cycle of the high side switches in each cell is 0.33. Duty cycle is chosen in accordance with the input and output voltages.

For example, the inductor layer 404 may comprise a switch S₅ coupled to an inductor L₁ and a switch S₆ coupled in parallel with the switch S₅ and inductor L₁. The first capacitor layer 402a may comprise an input voltage Vin coupled in series to a switch S₁ and a capacitor C₁. The capacitor C₁ is coupled in parallel with a switch S₃ and in parallel with an inductor L₃.

For example, a second capacitor layer 402b comprises a switch S₂ coupled in series with a capacitor C₂. The capacitor C₂ is coupled in parallel with a switch S₄ and in parallel with an inductor L₃.

The first capacitor layer 402a, the second capacitor layer 402b, and the inductor layer 404 may be coupled in parallel. One end of the switch S₅ of the inductor layer 404 is coupled between the switch S₂ and the capacitor C₂ of the second capacitor layer 402b. One end of the switch S₂ of the capacitor layer 402b is coupled between the switch S₁ and the capacitor C₁ of the capacitor layer 402a. A capacitor C_{F} is coupled in parallel with the inductors L₁, L₂, and L₃. A capacitor C_{O} is in parallel with the capacitor C_{F}. The output voltage V_{O} is in parallel with the capacitor C_{O}.

The control circuit (not shown) may control the switching frequency of each of the switches. For example, the duty cycle for switching may be equal to 3*(V_{O}/Vᵢₙ).

FIG. 14 is a circuit stack 500, according to an aspect of the present disclosure. The circuit stack 500 comprises four cells or layers, a first capacitor layer 502a, a second capacitor layer 502b, a third capacitor layer 502c, and an inductor layer 504. The maximum duty cycle of the high side switches in each cell is 0.25. Duty cycle is chosen in accordance with the input and output voltages.

For example, the inductor layer 504 may comprise a switch S₅ coupled to an inductor L₁ and a switch S₆ coupled in parallel with the switch S₅ and inductor L₁. The first capacitor layer 502a may comprise an input voltage Vin coupled in series to a switch S₁ and a capacitor C₁. The capacitor C₁ is coupled in parallel with a switch S₃ and in parallel with an inductor L₃.

For example, a second capacitor layer 502b comprises a switch S₂ coupled in series with a capacitor C₂. The capacitor C₂ is coupled in parallel with a switch S₄ and in parallel with an inductor L₃. For example, a third capacitor layer 502c may comprise a switch S₇ coupled in series with a capacitor C₃. The capacitor C₃ is coupled in parallel with a switch S₈ and in parallel with an inductor L₄.

For example, the first capacitor layer 502a, the second capacitor layer 502b, the third capacitor layer 502c, and the inductor layer 504 may be coupled in parallel. One end of the switch S₅ of the inductor layer 504 is coupled between the switch S₇ and the capacitor C₃. One end of the switch S₇ of the capacitor layer 502c is coupled between the switch S₂ and the capacitor C₂ of the second capacitor layer 402b. One end of the switch S₂ of the capacitor layer 502b is coupled between the switch S₁ and the capacitor C₁ of the first capacitor layer 502a.

A capacitor C_{F} may be coupled in parallel with the inductors L₁, L₂, and L₃. A capacitor C_{O} may be in parallel with the capacitor C_{F}. The output voltage V_{O} is in parallel with the capacitor C_{O}.

The control circuit (not shown) may control the switching frequency of each of the switches. For example, the duty cycle for switching may be equal to 4*(V_{O}/Vᵢₙ).

These configurations have greater transient response compared to single stage buck and scalability is achieved by utilizing a circuit with appropriate number of cells or layers. Each cell processes a fraction of the total power.

TABLE 2

| Input | Output | N-cell | Nominal Duty |
|---|---|---|---|
| Voltage (V) | Voltage (V) | SC-Buck | Cycle (%) |
| 12 | 1 | 2-cell | 16.7 |
| 12 | 0.5 | 2-cell or 3-cell | 8.3 or 12.5 |
| 12 | 5 | 1-cell (Conv. Buck: | 41.7 |
| | | building block 2 only) | |
| 28 | 1 | 2-cell or 3-cell | 7.1 or 10.7 |
| 28 | 0.5 | 4-cell | 7.1 |
| 48 | 1 | 4-cell | 8.3 |
| 48 | 0.5 | 6-cell | 6.25 |

Table 2 illustrates the number of cells or circuit layers needed to convert from an input voltage to an output voltage. Table 2 also illustrates the duty cycle at which the control circuit is to control the gate drive and the switches.

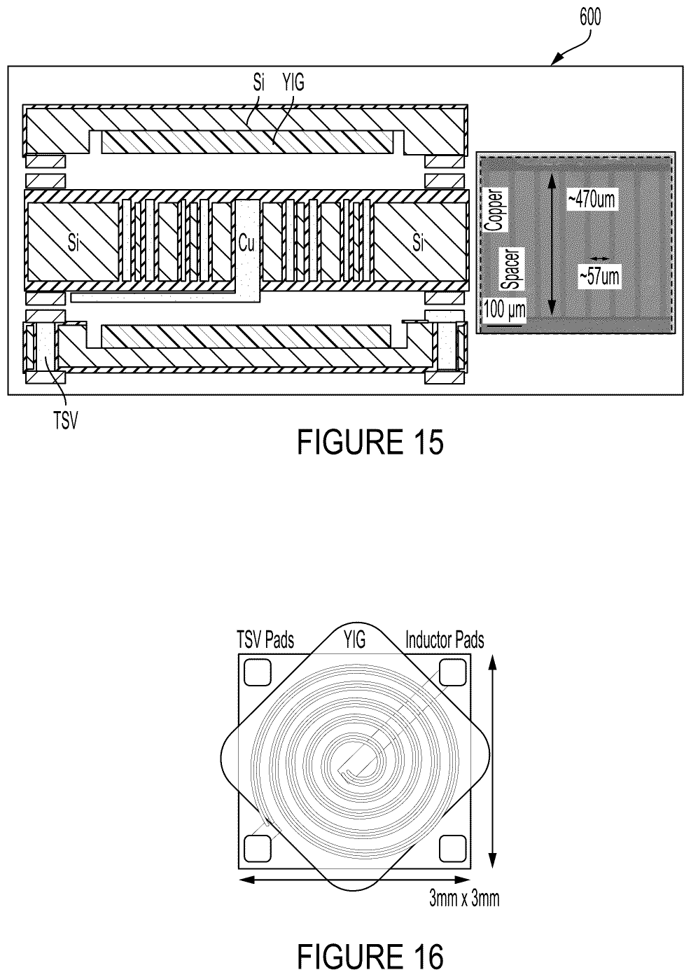

FIG. 15 is a cross-sectional view of a silicon-MEMS inductor. FIG. 16 illustrates the plan view of a 3D Silicon-MEMS inductor, according to an aspect of the present disclosure. MEMS inductor 600 is formed by a 3D stack comprised of a Si coil chip sandwiched between two yttrium iron garnet (YIG) magnetic material chips. The YIG chip is a 400 μm thick substrate featuring full-wafer thickness copper windings at aspect ratio of 10:1 to 20:1.

A magnetic field is created when copper windings carry current. If YIG was not included, then no chips with metal lines, pads, or interconnects can be placed in its proximity since the fringing magnetic field will create losses in the metal lines. Additionally, the bonding of the YIG layer increases inductance by ˜10 times. YIG maintains permeability and low loss over MHz switching frequencies. YIG also provides magnetic shielding to prevent fields on neighboring chips and interconnects to prevent eddy current losses. The required inductance density for the n-cell power converter of the present disclosure is achievable at about 3 to 7 nH/milli-ohm-mm2 with low series resistance of about 0.3 to 0.5 milliohms at 1-turn and 2.3 to 3.3 milliohms at 2 or 3-turn designs.

Without YIG, the magnetic field will spread such that no metal layers can be placed in proximity. This creates a “keep-away” region and prevents stacking of chips that contain metal interconnects and pads. YIG shields the magnetic field such that chips can be stacked in proximity to create chiplets.

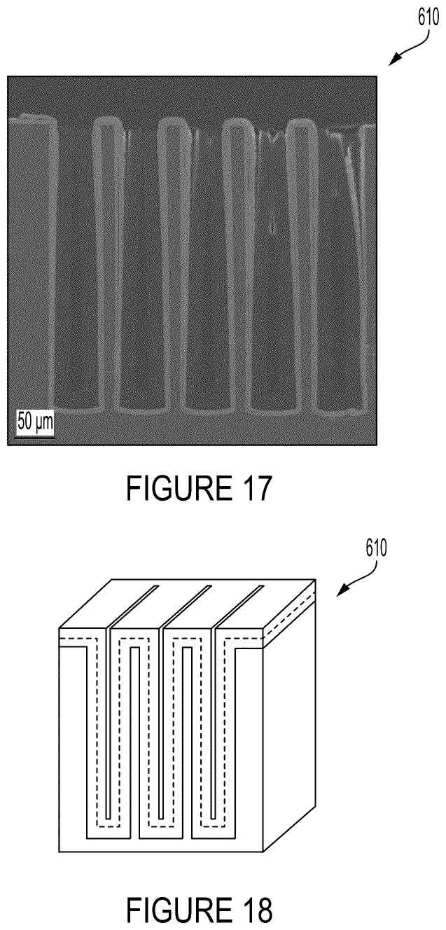

FIGS. 17 and 18 illustrate a 3D MEMS trench capacitor 610, according to an aspect of the present disclosure. A 3D MEMS trench capacitor 610 is disposed within the silicon of the circuit layer. The MEMS trench capacitor has a high capacitance density achievable within 3 mm by 3 mm area. The breakdown voltage of the capacitor is between 12V and 48V. The capacitor also has a low series resistance (<3 milliohms) to support high current with low power dissipation. The capacitor is compatible for integration by stacking with other components. The capacitor has low parasitic inductance such that self-resonance is at least 10 times higher than switching frequency and has the ability to withstand thermo-mechanical stresses from high current. Microfabricated high-aspect-ratio trench capacitor with conformal metal and dielectric layers are examples of such capacitors. Table 3 shows the capacitance at a 3 mm-by-3 mm size.

TABLE 3

| | 1 mΩ sheet | 2 mΩ sheet | 3 mΩ sheet |
|---|---|---|---|
| | resistance | resistance | resistance |
| 12 V | 179.7 nF | 223.2 nF | 243.6 nF |
| Withstanding | | | |
| 48 V | 43.1 nF | 53.6 nF | 58.5 nF |
| Withstanding | | | |

In terms of capacitance density, Table 4 shows the capacitance available per square millimeter physical area of the chip. The target physical chip area can then be derived from the target capacitance.

TABLE 4

| | 1 mΩ sheet | 2 mΩ sheet | 3 mΩ sheet |
|---|---|---|---|
| | resistance | resistance | resistance |
| 12 V | 20.0 nF/mm² | 24.8 nF/mm² | 27.1 nF/mm² |
| Withstanding | | | |
| 48 V | 4.79 nF/mm² | 5.95 nF/mm² | 6.50 nF/mm² |
| Withstanding | | | |

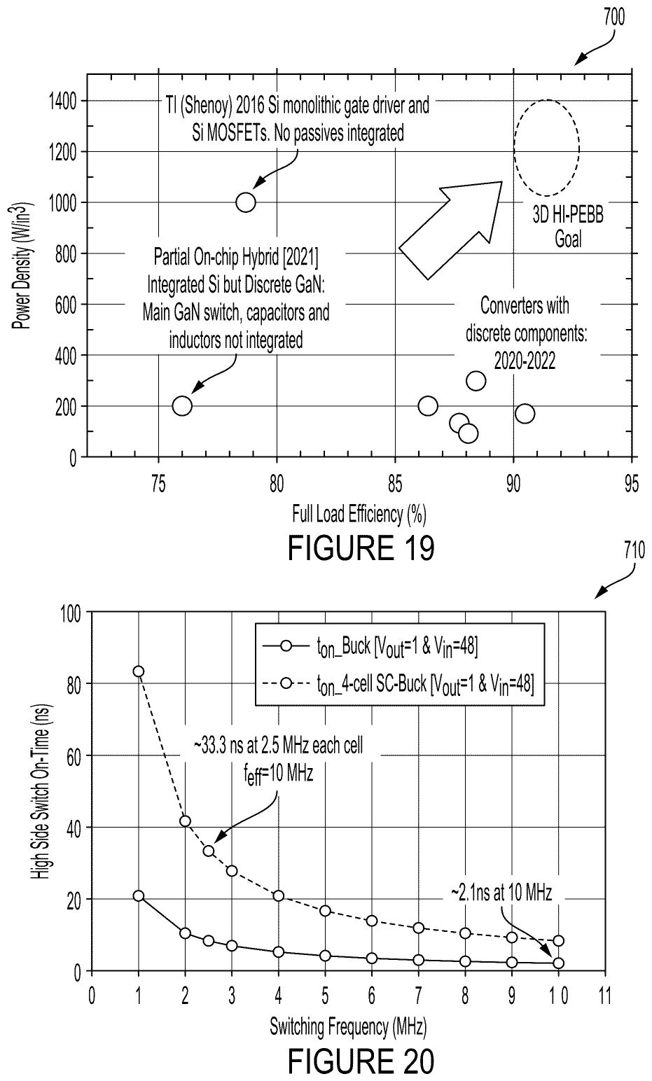

FIG. 19 illustrates a graph 700 of the full load efficiency and power density of common power converters in comparison with the power converter of the present disclosure. The power converter of the present disclosure has a higher power density and load efficiency than common power converters.

FIG. 20 illustrates a graph 710 of the on-time of the high side switch in a buck converter with switching frequency (red line) at input voltage of 48V and output voltage of 1V, compared to the power converter of the present disclosure. The buck converter has about four times lower on-time at the same switching frequency as the power converter of the present disclosure. A small on-time of the high side switch in the buck converter cannot be accurately controlled, which limits the switching frequency. Therefore, a conventional buck converter does not provide adequate voltage scaling and its low duty cycle limits switching frequency with an extremely short conduction time of high-side switch. This is inadequate to control output voltage. The power converter of the present disclosure is based on switched capacitor-buck topology, which allows higher switching frequency with precise output voltage control, smaller size of passives, and modularity.

The conventional buck converter has an on time equal to tₒₙ=Vₒᵤₜ/f_{sw}*Vᵢₙ. The 4-cell converter shown in FIG. 14 has an on time equal to tₒₙ=4*Vₒᵤₜ/f_{sw}*Vᵢₙ.

In one aspect, the power converter of the present disclosure is to turn on and off in approximately 2 ns each. A 2.1 ns on-period at 10 MHz switching frequency in a conventional buck is not feasible at 48V input and 1V output. The switched capacitor-buck (SC-buck) topology solves this problem of the present disclosure. The 4-cell power converter of the present disclosure enables ˜33.3 ns device on-period for the same effective frequency of 10 MHz at the load, where each cell of the 4-cell SC-buck switches at 2.5 MHz. Therefore, turn on and off periods at 2 ns each can be accomplished. The higher performance GaN devices can operate at ˜1.25 ns turn on and off periods and will therefore enable even higher switching frequency in each cell of SC-buck.

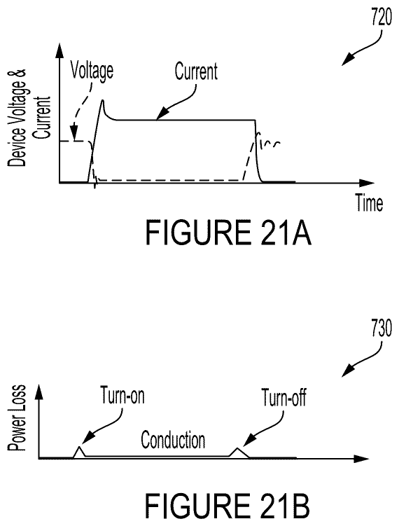

FIG. 21A illustrates a graph 720 of the voltage and current of the power converter of the present disclosure. FIG. 21B illustrates a graph 730 of the switching losses during turn on and turn off events of high-side switches in the power converter of the present disclosure. The turn on and turn off switching losses are smaller than the state-of-the-art buck converters (shown in FIGS. 4A and 4B) due to lower input voltage experienced by the high-side switches. This results in lower power loss.

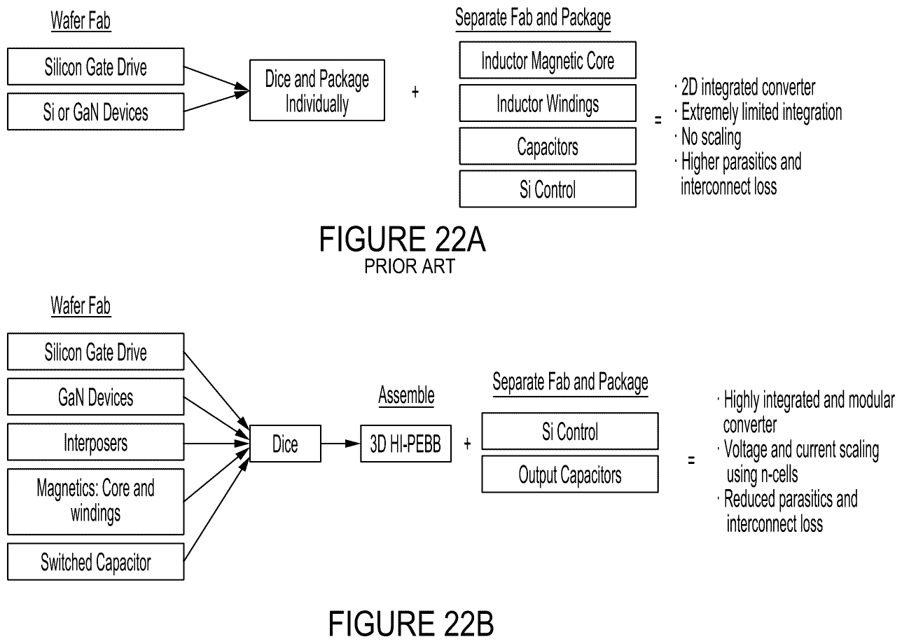

FIG. 22A illustrates a method of assembling a generally known power converter. FIG. 22B illustrates assembling the power converter of the present disclosure. The wafer fabrication utilizes silicon wafer gate drives, GaN devices, interposers, magnetic core and windings, and a switched capacitor. These are assembled into the stacked power converter. In comparison to the existing method, the need for separate fabrication and package is reduced to only two components (Si control and output capacitors) in the present disclosure. All the remaining components can be integrated into a 3D vertically stacked chip (3D HI-PEBB).

For example, a method of manufacturing a power converter includes fabricating on a wafer: a gate drive, a switch, a plurality of interposers, an inductor, and a capacitor. The method may also include dicing the wafer and assembling a stack comprising the gate drive, the switch, the plurality of interposers, the inductor, and the capacitor in a stacked configuration. The method may include fabricating the stack on a substrate and assembling a control circuit on the substrate.

The stack may be at least one of the first stack 308, the second stack 306, or combinations thereof. The method may also include fabricating output capacitors on the substrate.

Having thus described several aspects and embodiments of the technology of this application, it is to be appreciated that various alterations, modifications, and improvements will readily occur to those of ordinary skill in the art. Such alterations, modifications, and improvements are intended to be within the scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. The transitional phrases “consisting of” and “consisting essentially of” shall be closed or semi-closed transitional phrases, respectively.

Where a range or list of values is provided, each intervening value between the upper and lower limits of that range or list of values is individually contemplated and is encompassed within the disclosure as if each value were specifically enumerated herein. In addition, smaller ranges between and including the upper and lower limits of a given range are contemplated and encompassed within the disclosure. The listing of values or ranges is not a disclaimer of other values or ranges between and including the upper and lower limits of a given range.

The use of headings and sections in the application is not meant to limit the disclosure; each section can apply to any aspect, embodiment, or feature of the disclosure. Only those claims which use the words “means for” are intended to be interpreted under 35 USC 112(f). Absent a recital of “means for” in the claims, such claims should not be construed under 35 USC 112. Limitations from the specification are not intended to be read into any claims, unless such limitations are expressly included in the claims.

Embodiments disclosed herein may be embodied as a system, method or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, embodiments may take the form of a computer program product embodied in one or more computer readable medium(s) having computer readable program code embodied thereon.

What is claimed is:

1. A power converter comprising:
a substrate;
a control circuit disposed on the substrate; and
a first circuit stack disposed on the substrate and coupled to the control circuit, wherein the first circuit stack is in a stacked configuration, the first circuit stack comprising:
a first switch layer;
a first interposer layer electrically coupled to the first switch layer;
a second interposer layer electrically coupled to the first interposer layer;
a first gate drive layer disposed between and electrically coupled to the first interposer layer and the second interposer layer; and
a first inductor layer electrically coupled to the first gate drive layer.

2. The power converter of claim 1, wherein the first and second interposer layers define a plurality of through silicon vias for electrical coupling.

3. The power converter of claim 1, further comprising a second circuit stack disposed on the substrate and coupled to the control circuit, wherein the second circuit stack is in a stacked configuration, the second circuit stack comprising:
a second switch layer disposed on the substrate;
a third interposer layer electrically coupled to the second switch layer;
a fourth interposer layer electrically coupled to the third interposer layer;
a second gate drive layer disposed between and electrically coupled to the third interposer layer and the fourth interposer layer;
a capacitor layer electrically coupled to the fourth interposer layer within a fifth interposer layer; and
a second inductor layer coupled to the capacitor layer.

4. The power converter of claim 3, wherein the third, fourth, and fifth interposer layers defines a plurality of through silicon vias for electrical coupling.

5. The power converter of claim 3, wherein the second circuit stack comprises a plurality of capacitor layers between the second gate drive layer and the second inductor layer.

6. The power converter of claim 3, wherein the control circuit is to control switch timing of the first and second switch layer.

7. The power converter of claim 3, wherein the control circuit is to control which of the first and second circuit stack is to receive an input voltage and modulate an output voltage.

8. The power converter of claim 3, further comprising a plurality of second circuit stacks disposed on the substrate coupled to the control circuit.

9. The power converter of claim 3, wherein the capacitor layer comprises a microelectromechanical system (MEMS) blocking capacitor.

10. The power converter of claim 1, wherein the control circuit is to control timing of the first and second switch layer to control an output voltage.

11. The power converter of claim 1, wherein the first inductor layer comprises a microelectromechanical system (MEMS) power inductor.

12. The power converter of claim 1, wherein the first switch layer is comprised of gallium nitride with integrated high side and low side switches and diodes.

13. A power converter comprising:
a substrate;
a control circuit disposed on the substrate; and
a circuit stack disposed on the substrate and coupled to the control circuit, wherein the circuit stack is in a stacked configuration, the circuit stack comprising:
a switch layer disposed on the substrate;
a first interposer layer electrically coupled to the switch layer;
a second interposer layer electrically coupled to the first interposer layer;
a gate drive layer disposed between and electrically coupled to the first interposer layer and the second interposer layer;
a capacitor layer electrically coupled to the second interposer layer within a third interposer layer; and
an inductor layer coupled to the capacitor layer.

14. The power converter of claim 13, wherein the first, second, and third interposer layers defines a plurality of through silicon vias for electrical coupling.

15. The power converter of claim 13, wherein the circuit stack comprises a plurality of capacitor layers between the gate drive layer and the inductor layer.

16. The power converter of claim 13, wherein the control circuit is to control switch timing of the switch layer.

17. The power converter of claim 13, wherein the control circuit is to control timing of the switch layer to control an output voltage.

18. The power converter of claim 13, wherein the capacitor layer comprises a microelectromechanical system (MEMS) blocking capacitor.

19. A method of manufacturing a power converter, the method comprising:
fabricating on a wafer:
a gate drive;
a switch;
a plurality of interposers;
an inductor; and
a capacitor;
dicing the wafer;
assembling a stack comprising the gate drive, the switch, the plurality of interposers, the inductor, and the capacitor in a stacked configuration;
fabricating the stack on a substrate; and
assembling a control circuit on the substrate.

20. The method of claim 19, comprising fabricating output capacitors on the substrate.
